(19) United States
(12) Patent Application Publication
(10) Pub. No.: US 2024/0162870 A1
(43) Pub. Date: May 16, 2024

(54) BALANCED-UNBALANCED TRANSFORMER CIRCUIT AND AMPLIFIER CIRCUIT

(71) Applicant: Murata Manufacturing Co., Ltd., Kyoto (JP)

(72) Inventors: Masatoshi HASE, Kyoto (JP); Koudai SUGIYAMA, Kyoto (JP); Masamichi TOKUDA, Kyoto (JP); Seiko NETSU, Kyoto (JP)

(21) Appl. No.: 18/503,549

(22) Filed: Nov. 7, 2023

(30) Foreign Application Priority Data
Nov. 10, 2022 (JP) 2022-180503

(51) Int. Cl. H03F 3/45

(52) U.S. Cl. CPC H03F 3/45475; H03F 2200/06; H03F 2200/09; H03F 2200/451

(57) ABSTRACT

A main line (transmission line) having a first end and a second end. A sub-line (transmission line) coupled to the main line. An unbalanced signal is input to and output from an unbalanced node connected to the first end. A balanced signal is input to and output from a first balanced node and a second balanced node. The main line and the sub-line are coupled to each other. A direction of the main line is identical to a direction of the sub-line. The second end and the third end are connected to a reference potential. The first balanced node and the second balanced node are connected to the unbalanced node and the fourth end, respectively. A first LC resonant circuit is connected between the second end and the reference potential or the third end and the reference potential.

### CROSS REFERENCE TO RELATED APPLICATION

This application claims priority from Japanese Patent Application No. 2022-180503 filed on Nov. 10, 2022. The content of this application is incorporated herein by reference in its entirety.

### BACKGROUND ART

The present disclosure relates to a balanced-unbalanced transformer circuit and an amplifier circuit.

Chris Trask, “Transmission Line Transformers: Theory, Design and Applications-Part 2”, High Frequency Electronics, January 2006 discloses a choke balun that performs balanced-unbalanced transformation at an impedance conversion ratio of 1:1.

### BRIEF SUMMARY

There is a demand for a balanced-unbalanced transformer circuit that can be used for an amplifier circuit capable of reducing an interference wave.

The present disclosure provides a balanced-unbalanced transformer circuit capable of sufficiently removing an interference wave, and an amplifier circuit including the balanced-unbalanced transformer circuit.

According to an aspect of the present disclosure, there is provided a balanced-unbalanced transformer circuit including:
a main line constituted by a transmission line having a first end and a second end;
a sub-line coupled to the main line, the sub-line being constituted by a transmission line having a third end and a fourth end;
an unbalanced node to which an unbalanced signal is input and from which the unbalanced signal is output, the unbalanced node being connected to the first end; and
a first balanced node and a second balanced node to which a balanced signal is input and from which the balanced signal is output, in which
the main line and the sub-line are coupled to each other such that a direction from the first end toward the second end of the main line is identical to a direction from the third end toward the fourth end of the sub-line,
the second end and the third end are connected to a reference potential,
the first balanced node and the second balanced node are connected to the unbalanced node and the fourth end, respectively, and
the balanced-unbalanced transformer circuit further includes a first LC resonant circuit connected between the second end and the reference potential or between the third end and the reference potential.

According to another aspect of the present disclosure, there is provided an amplifier circuit including:
a first balanced-unbalanced transformer circuit configured to transform an unbalanced signal into a balanced signal;
a differential amplifier configured to amplify the balanced signal output from the first balanced-unbalanced transformer circuit; and
a second balanced-unbalanced transformer circuit configured to transform the balanced signal output from the differential amplifier into an unbalanced signal, in which
one of the first balanced-unbalanced transformer circuit and the second balanced-unbalanced transformer circuit is the foregoing balanced-unbalanced transformer circuit, operates as a balanced-unbalanced transformer circuit for a radio frequency signal of one of a first frequency and a second frequency, and does not operate as a balanced-unbalanced transformer circuit for a radio frequency signal of an other of the first frequency and the second frequency, and
an other of the first balanced-unbalanced transformer circuit and the second balanced-unbalanced transformer circuit operates as a balanced-unbalanced transformer circuit for a radio frequency signal of the first frequency and a radio frequency signal of the second frequency.

This amplifier circuit is capable of sufficiently removing an interference wave by using only passive elements. Thus, the cost can be reduced.

### BRIEF DESCRIPTION OF THE DRAWINGS

FIG. 1 is an equivalent circuit diagram of a balun according to a first embodiment;

FIG. 2 is an equivalent circuit diagram of a balun according to a second embodiment;

FIG. 3 is a schematic perspective view of a main line and a sub-line of the balun according to the second embodiment;

FIG. 4 is a graph schematically showing the frequency dependence of the common mode rejection ratio (CMRR) of the balun according to the second embodiment;

FIG. 5 is an equivalent circuit diagram of a balun according to a modification of the second embodiment;

FIG. 6 is a graph schematically showing the frequency dependence of the CMRR of the balun according to the modification of the second embodiment;

FIG. 7A and FIG. 7B are equivalent circuit diagrams of baluns according to other modifications of the second embodiment;

FIG. 8 is an equivalent circuit diagram of a balun according to a third embodiment;

FIG. 9 is an equivalent circuit diagram of a balun according to a fourth embodiment;

FIG. 10 is a graph illustrating a simulation result of the frequency dependence of the CMRR of the balun according to the fourth embodiment;

FIG. 11 is a block diagram of an amplifier circuit according to a fifth embodiment; and

FIG. 12 is a block diagram of an amplifier circuit according to a sixth embodiment.

### DETAILED DESCRIPTION

### First Embodiment

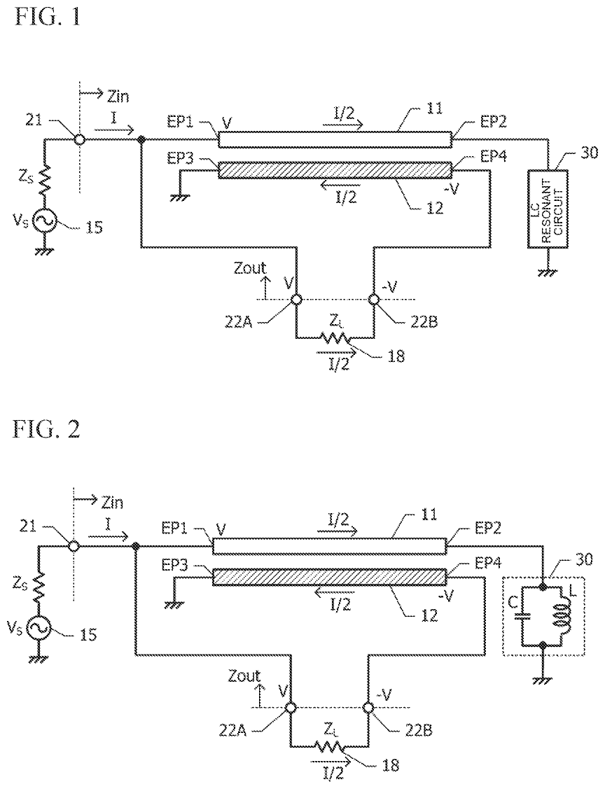

A balanced-unbalanced transformer circuit (balun) according to a first embodiment will be described with reference to FIG. 1.

FIG. 1 is an equivalent circuit diagram of the balun according to the first embodiment. The balun according to the first embodiment includes a main line 11 and a sub-line 12 each of which is constituted by a transmission line. The main line 11 and the sub-line 12 constitute a Ruthroff transmission line transformer. One end portion of the main line 11 is referred to as a first end EP1, and the other end portion thereof is referred to as a second end EP2. One end portion of the sub-line 12 is referred to as a third end EP3, and the other end portion thereof is referred to as a fourth end EP4. The main line 11 and the sub-line 12 are coupled to each other such that the direction from the first end EP1 toward the second end EP2 of the main line 11 is identical to the direction from the third end EP3 toward the fourth end EP4 of the sub-line 12.

The first end EP1 of the main line 11 is connected to an unbalanced node 21 to which an unbalanced signal is input and from which the unbalanced signal is output. The second end EP2 of the main line 11 is connected to a reference potential (ground potential). Here, “connected” includes both a case of being directly connected and a case of being connected via a passive element. An LC resonant circuit 30 is connected between the second end EP2 and the reference potential. The LC resonant circuit 30 includes at least one inductor and at least one capacitor, and has at least one resonant frequency.

The first end EP1 of the main line 11 is further connected to a first balanced node 22A, which is one of a pair of balanced nodes to which a balanced signal is input and from which the balanced signal is output. A second balanced node 22B, which is the other balanced node, is connected to the fourth end EP4 of the sub-line 12. The third end EP3 of the sub-line 12 is connected to a reference potential.

An unbalanced signal is input to the unbalanced node 21 from a radio frequency (RF) signal source 15 having an output impedance Z_{S}. A load 18 is connected between the first balanced node 22A and the second balanced node 22B. A current entered through the unbalanced node 21 is divided into a current flowing toward the main line 11 and a current flowing toward the sub-line 12.

The output voltage of the RF signal source 15 is denoted by Vs, and the input impedance on the load side as seen from the unbalanced node 21 is denoted by Zin. The load impedance of the load 18 is denoted by Z_{L}. The output impedance on the input side as seen from the first balanced node 22A and the second balanced node 22B is denoted by Zout.

Next, the operation of the balun according to the first embodiment will be described. First, a description will be given of a case where the LC resonant circuit 30 can be regarded as being substantially short-circuited at the frequency of an RF signal input to the unbalanced node 21.

A current that flows into the balun from the unbalanced node 21 is denoted by I. When an RF current flows through the main line 11, an induced current in an odd mode flows through the sub-line 12. The magnitude of the induced current flowing through the sub-line 12 is equal to the magnitude of the RF current flowing through the main line 11, and the phase of the induced current flowing through the sub-line 12 is inverted with respect to the phase of the RF current flowing through the main line 11. Thus, the RF current I input to the unbalanced node 21 is equally divided into a current flowing through the main line 11 and a current flowing through the sub-line 12. That is, the magnitude of the current flowing through the main line 11 and the magnitude of the current flowing through the sub-line 12 are each equal to I/2.

The potential at the first end EP1 of the main line 11 is denoted by V. When the LC resonant circuit 30 can be regarded as being substantially short-circuited, the potential at the second end EP2 of the main line 11 is 0. That is, the potential difference between both ends of the main line 11 is equal to V. At this time, the potential difference between both ends of the sub-line 12 is also equal to V. The potential at the third end EP3 of the sub-line 12 is 0, and thus the potential at the fourth end EP4 is equal to −V. That is, the potential at the first balanced node 22A is V, and the potential at the second balanced node 22B is −V. The current flowing through the load 18 is equal to I/2.

When the potential at the unbalanced node 21 is V and the current entering through the unbalanced node 21 is I, the potential difference between the first balanced node 22A and the second balanced node 22B is 2 V, and the current flowing through the load 18 is I/2. Thus, the output impedance Zout is four times the input impedance Zin. The balun according to the first embodiment transforms an unbalanced signal input from the unbalanced node 21 into a balanced signal, outputs the balanced signal from the first balanced node 22A and the second balanced node 22B, and performs impedance conversion.

Alternatively, the first balanced node 22A and the second balanced node 22B may be used as input nodes, and the unbalanced node 21 may be used as an output node. In this case, the balun according to the first embodiment transforms a balanced signal input from the first balanced node 22A and the second balanced node 22B into an unbalanced signal, outputs the unbalanced signal from the unbalanced node 21, and performs impedance conversion.

Next, a description will be given of a case where the LC resonant circuit 30 cannot be regarded as being short-circuited at the frequency of an RF signal input to the unbalanced node 21. For example, a description will be given of a case where the impedance of the LC resonant circuit 30 is infinite or very large at the frequency of an RF signal input to the unbalanced node 21.

At this time, the second end EP2 of the main line 11 cannot be regarded as being short-circuited to the ground potential. Thus, the balun according to the first embodiment does not exhibit a balanced-unbalanced transforming function. For example, when the common mode rejection ratio (CMRR) of the balun is 20 dB or less, the balun does not exhibit a balanced-unbalanced transforming function. In this way, the balanced-unbalanced transforming function of the balun according to the first embodiment has frequency dependence. In other words, the CMRR of the balun according to the first embodiment has frequency dependence.

Next, excellent effects of the first embodiment will be described.

In the first embodiment, adjusting of the resonant frequency of the LC resonant circuit 30 enables the CMRR of the balun to have desired frequency dependence.

### Second Embodiment

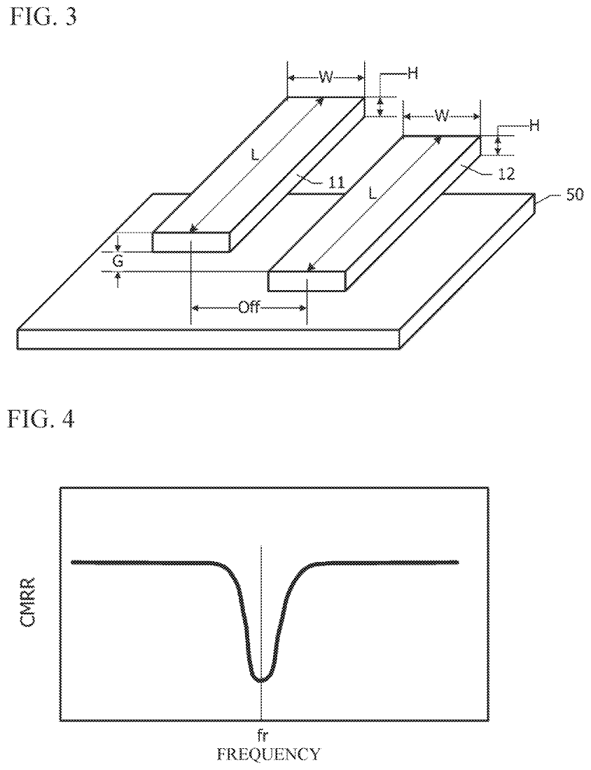

Next, a balun according to a second embodiment will be described with reference to FIG. 2, FIG. 3, and FIG. 4. Hereinafter, a description of the same components as those of the balun according to the first embodiment (FIG. 1) will be omitted.

FIG. 2 is an equivalent circuit diagram of the balun according to the second embodiment. In the first embodiment (FIG. 1), a specific configuration of the LC resonant circuit 30 is not illustrated. In the second embodiment, the LC resonant circuit 30 is constituted by an LC parallel resonant circuit. At the resonant frequency of the LC resonant circuit 30, the portion between the second end EP2 of the main line 11 and the ground potential is substantially open. Thus, the balun according to the second embodiment does not exhibit a balanced-unbalanced transforming function. In a frequency range away from the resonant frequency, the balun according to the second embodiment exhibits a balanced-unbalanced transforming function.

FIG. 3 is a schematic perspective view of the main line 11 and the sub-line 12. The main line 11 and the sub-line 12 are constituted by wiring lines in a multilayer wiring structure disposed on an upper surface of a substrate 50, which is one surface of the substrate 50. The main line 11 and the sub-line 12 are disposed in wiring layers different from each other. For example, the sub-line 12 is disposed at a position lower than the main line 11, with the upper surface of the substrate 50 being a reference of height. In plan view, the main line 11 and the sub-line 12 are parallel to each other.

The line length, the width, and the height of the main line 11 are denoted by L, W, and H, respectively. The sub-line 12 has a line length, a width, and a height that are equal to the length, the width, and the height of the main line 11, respectively. The sub-line 12 is disposed so as to be offset in the width direction with respect to the main line 11. The amount of offset is denoted by Off. A gap between the main line 11 and the sub-line 12 in the height direction is denoted by G. In FIG. 3, the main line 11 and the sub-line 12 extend linearly, but both the lines may extend spirally.

FIG. 4 is a graph schematically showing the frequency dependence of the common mode rejection ratio (CMRR) of the balun according to the second embodiment. The horizontal axis represents frequency, and the vertical axis represents CMRR. At the resonant frequency fr of the LC resonant circuit 30 (FIG. 2), the LC resonant circuit 30 is open, and the balun does not exhibit a balanced-unbalanced transforming function. This causes the CMRR to be decreased. In a frequency range away from the resonant frequency fr, the balun according to the second embodiment exhibits a balanced-unbalanced transforming function, and thus the CMRR increases.

Next, excellent effects of the second embodiment will be described.

The balun according to the second embodiment does not function as a balun at and around the resonant frequency of the LC resonant circuit 30. In this way, the function of the balun can have frequency selectivity. For example, the balun can have frequency selectivity so that the balun functions as a balun in a frequency band including an input signal and that the balun does not function as a balun in a frequency band of an interference wave. With use of this function, it is possible to configure an amplifier circuit that amplifies an input signal and attenuates an interference wave, as will be described below.

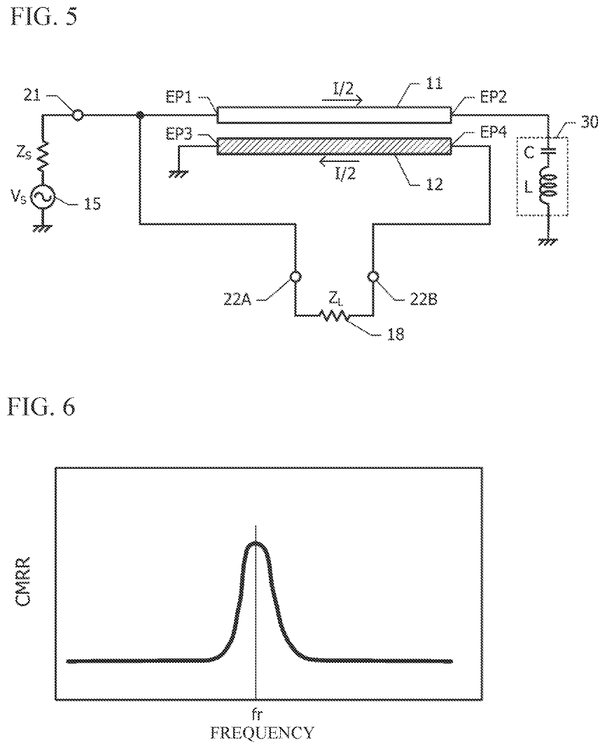

Next, a balun according to a modification of the second embodiment will be described with reference to FIG. 5 and FIG. 6.

FIG. 5 is an equivalent circuit diagram of the balun according to the modification of the second embodiment. In the second embodiment (FIG. 2), an LC parallel resonant circuit is used as the LC resonant circuit 30. In the modification of the second embodiment illustrated in FIG. 5, an LC series resonant circuit is used as the LC resonant circuit 30. The LC resonant circuit 30 is in a short-circuited state at the resonant frequency. Thus, the balun according to the modification of the second embodiment functions as a balun at the resonant frequency of the LC resonant circuit 30, and does not exhibit a balanced-unbalanced transforming function in a frequency range away from the resonant frequency.

FIG. 6 is a graph schematically showing the frequency dependence of the CMRR of the balun according to the modification of the second embodiment. The horizontal axis represents frequency, and the vertical axis represents CMRR. At the resonant frequency fr of the LC resonant circuit 30 (FIG. 5), the balun exhibits a balanced-unbalanced transforming function, and thus the CMRR increases. In a frequency range away from the resonant frequency fr, the balun according to the modification of the second embodiment does not exhibit a balanced-unbalanced transforming function, and thus the CMRR decreases.

Also in the modification of the second embodiment illustrated in FIG. 5 and FIG. 6, the function of the balun can have frequency selectivity. For example, the balun can have frequency selectivity so that the balun functions as a balun in a frequency band including an input signal and that the balun does not function as a balun in a frequency band of an interference wave. With use of this function, it is possible to configure an amplifier circuit that amplifies an input signal and attenuates an interference wave, as will be described below.

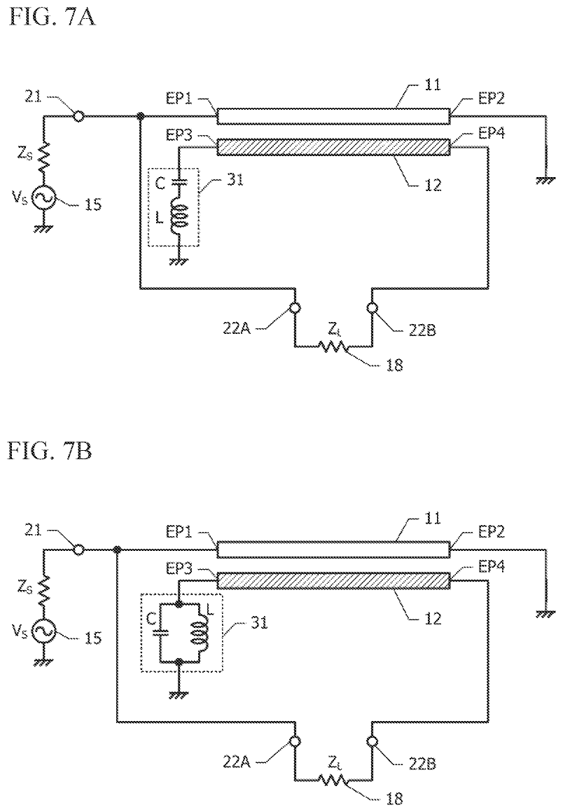

Next, other modifications of the second embodiment will be described with reference to FIG. 7A and FIG. 7B. FIG. 7A and FIG. 7B are equivalent circuit diagrams of baluns according to other modifications of the second embodiment. In the second embodiment (FIG. 2), the LC resonant circuit 30 is connected between the second end EP2 of the main line 11 and the reference potential. In contrast, in the modifications illustrated in FIG. 7A and FIG. 7B, an LC resonant circuit 31 is connected between the third end EP3 of the sub-line 12 and the reference potential, and the second end EP2 is short-circuited to the reference potential. In the modification illustrated in FIG. 7A, an LC series resonant circuit is used as the LC resonant circuit 31. In the modification illustrated in FIG. 7B, an LC parallel resonant circuit is used as the LC resonant circuit 31.

Similarly to the second embodiment (FIG. 2), the balun can have frequency selectivity also when the LC resonant circuit 31 is connected between the third end EP3 of the sub-line 12 and the reference potential, as in the modifications illustrated in FIG. 7A and FIG. 7B.

### Third Embodiment

Next, a balun according to a third embodiment will be described with reference to FIG. 8. Hereinafter, a description of the same components as those of the balun according to the second embodiment described with reference to FIG. 2 to FIG. 4 will be omitted.

FIG. 8 is an equivalent circuit diagram of the balun according to the third embodiment. In the second embodiment (FIG. 2), the LC resonant circuit 30 is connected between the second end EP2 of the main line 11 and the reference potential. In the modifications of the second embodiment illustrated in FIG. 7A and FIG. 7B, the LC resonant circuit 31 is connected between the third end EP3 of the sub-line 12 and the reference potential. In contrast, in the third embodiment, the LC resonant circuit 30 is connected between the second end EP2 and the reference potential, and the LC resonant circuit 31 is connected between the third end EP3 and the reference potential. An LC parallel resonant circuit is used as each of the LC resonant circuits 30 and 31.

Next, excellent effects of the third embodiment will be described.

When the two LC resonant circuits 30 and 31 have the same resonant frequency, the frequency selectivity of the balun can be enhanced. For example, the peak of the CMRR at the resonant frequency fr illustrated in FIG. 4 can be sharpened.

When the two LC resonant circuits 30 and 31 have different resonant frequencies, the balun can have frequency selectivity in a plurality of frequency bands. For example, in the graph showing the frequency dependence of CMRR illustrated in FIG. 4, it is possible to provide such a characteristic that the CMRR decreases at two positions on the frequency axis.

Next, a modification of the third embodiment will be described.

In the third embodiment (FIG. 8), both of the two LC resonant circuits 30 and 31 are LC parallel resonant circuits, but one of the LC resonant circuits 30 and 31 may be an LC series resonant circuit. As illustrated in FIG. 6, the CMRR decreases in a frequency range away from the resonant frequency of the LC series resonant circuit. The CMRR decreases at the resonant frequency of the LC parallel resonant circuit as illustrated in FIG. 4. Thus, the CMRR can be further decreased at the resonant frequency of the LC parallel resonant circuit in the graph of the CMRR illustrated in FIG. 6.

Both of the two LC resonant circuits 30 and 31 may be LC series resonant circuits, and may have the same resonant frequency. In this case, in the graph illustrated in FIG. 6, the peak of the CMRR appearing at the resonant frequency fr can be further sharpened.

### Fourth Embodiment

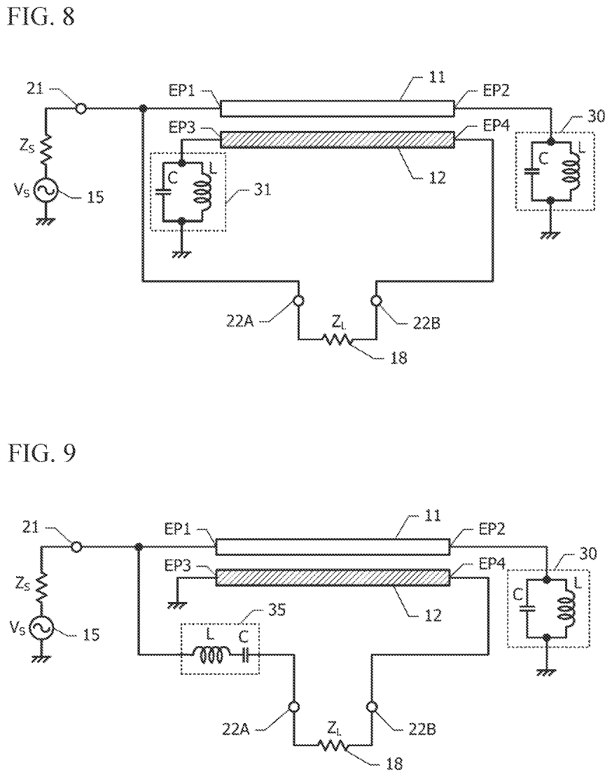

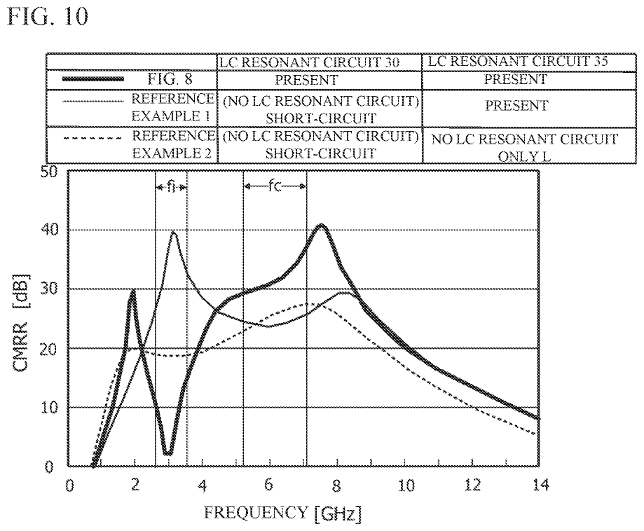

Next, a balun according to a fourth embodiment will be described with reference to FIG. 9 and FIG. 10. Hereinafter, a description of the same components as those of the balun according to the second embodiment described with reference to FIG. 2 to FIG. 4 will be omitted.

FIG. 9 is an equivalent circuit diagram of the balun according to the fourth embodiment. In the second embodiment (FIG. 2), the first balanced node 22A is connected directly to the unbalanced node 21. In contrast, in the fourth embodiment, an LC resonant circuit 35 is connected between the first balanced node 22A and the unbalanced node 21. The LC resonant circuit 35 has a function of compensating for the phase imbalance between a current flowing from the unbalanced node 21 toward the main line 11 and a current flowing from the unbalanced node 21 toward the sub-line 12 at a branch point therebetween.

For example, when an inductor or a capacitor is connected instead of the LC resonant circuit 35, appropriate phase compensation can be performed at a specific frequency. However, it is impossible to perform sufficient phase compensation at the other frequencies. The LC resonant circuit 35 exhibits an inductive impedance at a frequency lower than the resonant frequency, and exhibits a capacitive impedance at a frequency higher than the resonant frequency. This makes it possible to perform appropriate phase compensation in two ranges: the frequency range in which an inductive impedance is exhibited and the frequency range in which a capacitive impedance is exhibited.

FIG. 10 is a graph illustrating a simulation result of the frequency dependence of the CMRR of the balun according to the fourth embodiment. The horizontal axis represents frequency in the unit of GHz, and the vertical axis represents CMRR in the unit of dB. The balun as a simulation target has the following configuration.

The main line 11 and the sub-line 12 (FIG. 3) each has a line length L of 2100 μm, a width W of 5 μm, and a height H of 3.4 μm. The gap G between the main line 11 and the sub-line 12 in the height direction is 0.67 μm. The offset amount Off between the main line 11 and the sub-line 12 is 4 μm. The LC resonant circuit 30 has a capacitance of 5.2 pF, an inductance of 0.6 nH, and a resonant frequency of 2.85 GHz. That is, the balun according to the fourth embodiment does not operate as a balun in a frequency band fi including a frequency of 2.85 GHz.

The LC resonant circuit 35 has a capacitance of 3.0 pF and an inductance of 0.6 nH. The LC resonant circuit 35 has a resonant frequency of 3.75 GHz. That is, the balun according to the fourth embodiment is designed so as to function as a balun in the frequency band higher than 3.75 GHz and a frequency band fc higher than 3.75 GHz.

The thick solid line in the graph illustrated in FIG. 10 indicates the CMRR of the balun according to the fourth embodiment illustrated in FIG. 9. For comparison, the thin solid line indicates the CMRR of a configuration in which the portion at which the LC resonant circuit 30 is connected is short-circuited (reference example 1), and the broken line indicates the CMRR of a configuration in which the portion at which the LC resonant circuit 30 is connected is short-circuited and an inductor is connected instead of the LC resonant circuit 35 (reference example 2).

When an inductor is connected instead of the LC resonant circuit 35, the CMRR is higher in the frequency band fc than in the other frequency ranges, as indicated by the broken line in FIG. 10. On the other hand, when the LC resonant circuit 35 is connected, as indicated by the thin solid line in FIG. 10, the CMRR is higher in two frequency ranges: the frequency band fi and the vicinity of 8.5 GHz, than in the other frequency ranges. That is, the balun in which the LC resonant circuit 35 is connected functions as a balun in two frequency ranges: the frequency band fi and the vicinity of 8.5 GHz.

When both the LC resonant circuits 30 and 35 are connected, the CMRR decreases in the frequency band fi due to the influence of the LC resonant circuit 30, as indicated by the thick solid line in FIG. 10. That is, the balun according to the fourth embodiment functions as a balun in the frequency band fc, and does not function as a balun in the frequency band fi. The CMRR has a maximum value in the vicinity of 8 GHz, and has a sufficiently large value in the frequency band fc lower than 8 GHz.

Next, excellent effects of the fourth embodiment will be described.

The balun according to the fourth embodiment functions as a balun in a specific frequency band, for example, the frequency band fc illustrated in FIG. 10, and does not function as a balun in another specific frequency band, for example, the frequency band fi illustrated in FIG. 10. In this way, the balun can have frequency selectivity. Furthermore, as a result of connecting the LC resonant circuit 35, the degree of freedom of frequency selectivity can be increased as compared with the second embodiment (FIG. 4) and the modification of the second embodiment (FIG. 6).

### Fifth Embodiment

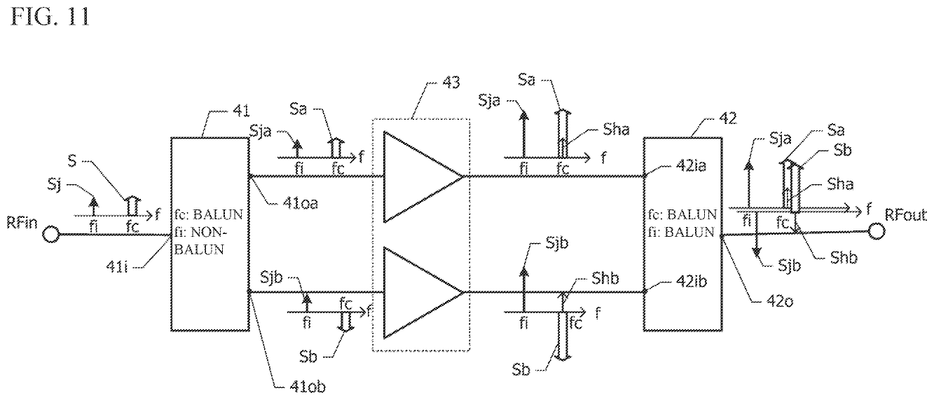

Next, an amplifier circuit according to a fifth embodiment will be described with reference to FIG. 11. The amplifier circuit according to the fifth embodiment includes the balun according to the second embodiment, the third embodiment, or the fourth embodiment.

FIG. 11 is a block diagram of the amplifier circuit according to the fifth embodiment. The amplifier circuit according to the fifth embodiment includes an input balun 41, a differential amplifier 43, and an output balun 42. An unbalanced signal input from an input terminal RFin is input to an unbalanced node 41i of the input balun 41. The input balun 41 transforms the unbalanced frequency signal into a balanced signal. The balanced signal obtained through the transformation is output from a pair of balanced nodes 41oa and 41ob. The balanced signal output from the input balun 41 is amplified by the differential amplifier 43 and is input to balanced nodes 42ia and 42ib of the output balun 42. The output balun 42 transforms the balanced signal into an unbalanced signal. The unbalanced signal obtained through the transformation is output from an unbalanced node 42o. The unbalanced node 42o of the output balun 42 is connected to an output terminal RFout.

The balun according to the second embodiment, the third embodiment, or the fourth embodiment is used as the input balun 41. The unbalanced node 41i and the pair of balanced nodes 41oa and 41ob of the input balun 41 correspond to the unbalanced node 21, the first balanced node 22A, and the second balanced node 22B of the balun according to the fourth embodiment illustrated in FIG. 9, respectively. The input balun 41 operates as a balun for an RF signal in the frequency band fc, but does not operate as a balun for an RF signal in the frequency band fi, which is ½ of the frequency band fc, for example, as indicated by the thick solid line in FIG. 10.

The output balun 42 operates as a balun in both the frequency band fc and the frequency band fi, which is ½ of the frequency band fc. For example, the balun according to reference example 1 that operates as a balun in both of the frequency bands fi and fc as indicated by the thin solid line in FIG. 10 is used as the output balun 42.

In FIG. 11, the graphs illustrated between the input terminal RFin and the input balun 41, between the input balun 41 and the differential amplifier 43, between the differential amplifier 43 and the output balun 42, and between the output balun 42 and the output terminal RFout schematically show the magnitudes and phases of RF signals in the frequency bands fi and fc. The horizontal axis represents frequency. The vertical axis represents signal magnitude. An upward arrow and a downward arrow mean that the phases are inverted with respect to each other.

Next, the operation of the amplifier circuit according to the fifth embodiment will be described. An input signal S in the frequency band fc is input to the input balun 41. In addition to the input signal S, an interference wave Sj in the frequency band fi is also input. For example, the frequency of the frequency band fi of the interference wave Sj is ½ of the frequency of the frequency band fc of the input signal S.

As an example, a frequency band of ½ of the frequencies of band UNII-1 (5150 MHz or more and 5250 MHz or less) and band UNII-2 (5250 MHz or more and 5350 MHz or less) of Wi-Fi overlaps the cellular band B41 (frequencies of 2496 MHz or more and 2690 MHz or less). Thus, an RF signal in the cellular band B41 may become an interference wave with respect to RF signals in the bands UNII-1 and UNII-2 of Wi-Fi. In addition, a frequency band of ½ of the frequencies of band UNII-7 (6525 MHz or more and 6875 MHz or less) and band UNII-8 (6875 MHz or more and 7125 MHz or less) of Wi-Fi overlaps the cellular band N77 (frequencies of 3300 MHz or more and 4200 MHz or less). Thus, an RF signal in the cellular band N77 may become an interference wave with respect to RF signals in the bands UNII-7 and UNII-8 of Wi-Fi.

The input signal S is transformed into a balanced signal by the input balun 41, and RF signals Sa and Sb are output from the balanced nodes 41oa and 41ob, respectively. The phases of the RF signals Sa and Sb are inverted with respect to each other. In the frequency band fi of the interference wave Sj, the input balun 41 does not operate as a balun, and thus interference waves Sja and Sjb having the same phase are output from the two balanced nodes 41oa and 41ob, respectively.

The RF signal Sa and the interference wave Sja are amplified by one amplifier of the differential amplifier 43, and the amplified RF signal Sa and interference wave Sja are output. The RF signal Sb and the interference wave Sjb are amplified by the other amplifier of the differential amplifier 43, and the amplified RF signal Sb and interference wave Sjb are output. The two amplifiers constituting the differential amplifier 43 have the same gain and the same phase characteristics. Thus, the magnitudes of the amplified RF signals Sa and Sb are equal to each other, and the phase of the amplified RF signal Sb remains inverted with respect to the phase of the RF signal Sa. The magnitudes of the amplified interference waves Sja and Sjb are equal to each other, and both the interference waves remain in phase.

Furthermore, the nonlinearity of the differential amplifier 43 produces second-order harmonics Sha and Shb of the interference waves Sja and Sjb. The phases of even-order harmonics of the interference waves Sja and Sjb are the same regardless of the phase relationship between the interference waves Sja and Sjb. Thus, the second-order harmonics Sha and Shb are in phase.

The RF signal Sa, the interference wave Sja, and the second-order harmonic Sha output from the differential amplifier 43 are input to one balanced node 42ia of the output balun 42, and the RF signal Sb, the interference wave Sjb, and the second-order harmonic Shb are input to the other balanced node 42ib of the output balun 42. These signals are transformed into unbalanced signals by the output balun 42. The output balun 42 operates as a balun for signals in both the frequency bands fi and fc. Thus, the RF signal Sa, the interference wave Sja, and the second-order harmonic Sha input to one balanced node 42ia are output with the phases thereof not being inverted, and the RF signal Sb, the interference wave Sjb, and the second-order harmonic Shb input to the other balanced node 42ib are output with the phases thereof being inverted.

The interference waves Sja and Sjb output from the unbalanced node 42o of the output balun 42 cancel each other because the phases thereof are inverted with respect to each other. The second-order harmonics Sha and Shb output from the unbalanced node 42o of the output balun 42 cancel each other because the phases thereof are inverted with respect to each other. The RF signals Sa and Sb output from the unbalanced node 42o of the output balun 42 are in phase and are thus added together.

Next, excellent effects of the fifth embodiment will be described.

In the amplifier circuit according to the fifth embodiment, the interference waves Sja and Sjb cancel each other, and the second-order harmonics Sha and Shb cancel each other. Thus, it is possible to reduce an increase in deterioration of the noise figure. This makes it possible to implement an amplifier, for example, an RF amplifier, which is less likely to be affected by the interference wave Sj. Furthermore, it is optional to insert a filter for reducing an interference wave in the circuit on the input side of the differential amplifier 43, and thus the insertion loss of the filter does not occur. As a result, a required gain of the differential amplifier 43 is reduced, and the current consumption can be reduced.

### Sixth Embodiment

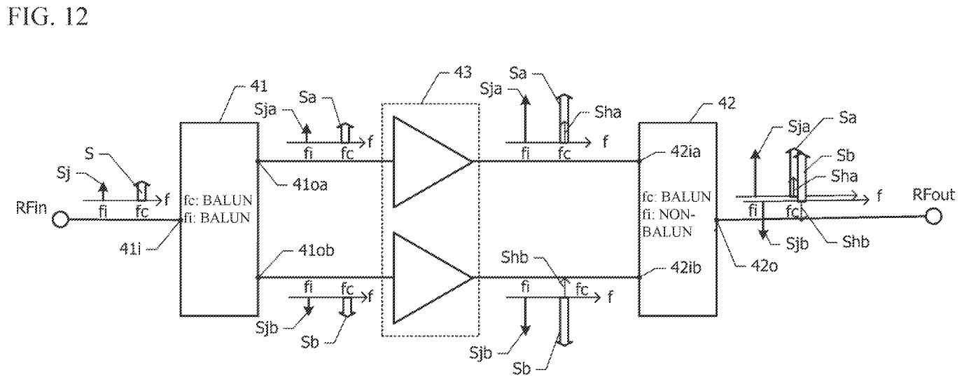

Next, an amplifier circuit according to a sixth embodiment will be described with reference to FIG. 12. Hereinafter, a description of the same components as those of the amplifier circuit according to the fifth embodiment described with reference to FIG. 11 will be omitted.

FIG. 12 is a block diagram of the amplifier circuit according to the sixth embodiment. In the fifth embodiment (FIG. 11), the input balun 41 operates as a balun in the frequency band fc, and does not operate as a balun in the frequency band fi. In contrast, in the sixth embodiment, the input balun 41 operates as a balun in both the frequency band fc and the frequency band fi, which is ½ of the frequency band fc. For example, the balun according to reference example 1 that operates as a balun in both of the frequency bands fi and fc as indicated by the thin solid line in FIG. 10 is used as the input balun 41.

In the fifth embodiment (FIG. 11), the output balun 42 operates as a balun in both the frequency bands fc and fi. In contrast, in the sixth embodiment, the balun according to the second embodiment, the third embodiment, or the fourth embodiment is used as the output balun 42. The output balun 42 operates as a balun for an RF signal in the frequency band fc, but does not operate as a balun for an RF signal in the frequency band fi, which is ½ of the frequency band fc, for example, as indicated by the thick solid line in FIG. 10.

In the fifth embodiment (FIG. 11), the input balun 41 does not operate as a balun in the frequency band fi, and thus the interference waves Sja and Sjb output from the pair of balanced nodes 41oa and 41ob are in phase. In contrast, in the sixth embodiment, the input balun 41 operates as a balun also in the frequency band fi. Thus, the phase of the interference wave Sjb output from one balanced node 41ob is inverted with respect to the phase of the interference wave Sja output from the other balanced node 41oa. The phase of the interference wave Sjb amplified by the differential amplifier 43 is also inverted with respect to the phase of the interference wave Sja.

Even if the phases of the interference waves Sja and Sjb are inverted with respect to each other, the second-order harmonics Sha and Shb of the interference waves Sja and Sjb are in phase.

The output balun 42 does not operate as a balun in the frequency band fi, and thus the phase of the interference wave Sjb output from the unbalanced node 42o of the output balun 42 remains inverted with respect to the phase of the interference wave Sja. The output balun 42 operates as a balun in the frequency band fc, and thus the interference waves Sja and Sjb that are in phase when being input to the output balun 42 have phases inverted with respect to each other when being output from the unbalanced node 42o. The phase relationship between the RF signals Sa and Sb is the same as the phase relationship between these signals in the amplifier circuit according to the fifth embodiment (FIG. 11).

Next, excellent effects of the sixth embodiment will be described. In the sixth embodiment, as in the fifth embodiment, the interference waves Sja and Sjb output from the unbalanced node 42o cancel each other, and the second-order harmonics Sha and Shb cancel each other. Thus, it is possible to reduce deterioration of the noise figure and an increase in current consumption. This makes it possible to implement an amplifier, for example, an RF amplifier, which is less likely to be affected by the interference wave Sj.

Each of the above-described embodiments is an example, and it is obviously possible to partially replace or combine the elements illustrated in different embodiments. Similar functions and effects obtained from similar configurations of a plurality of embodiments are not repeatedly described in each embodiment. Furthermore, the present disclosure is not limited to the embodiments described above. For example, it will be obvious to those skilled in the art that various modifications, improvements, combinations, and the like are possible.

On the basis of the above embodiments described in this specification, the following disclosures are disclosed.

<1>

A balanced-unbalanced transformer circuit including:
a main line constituted by a transmission line having a first end and a second end;
a sub-line coupled to the main line, the sub-line being constituted by a transmission line having a third end and a fourth end;
an unbalanced node to which an unbalanced signal is input and from which the unbalanced signal is output, the unbalanced node being connected to the first end; and
a first balanced node and a second balanced node to which a balanced signal is input and from which the balanced signal is output, in which
the main line and the sub-line are coupled to each other such that a direction from the first end toward the second end of the main line is identical to a direction from the third end toward the fourth end of the sub-line,
the second end and the third end are connected to a reference potential,
the first balanced node and the second balanced node are connected to the unbalanced node and the fourth end, respectively, and
the balanced-unbalanced transformer circuit further includes a first LC resonant circuit connected between the second end and the reference potential or between the third end and the reference potential.

<2>

The balanced-unbalanced transformer circuit according to <1>, in which the first LC resonant circuit is an LC series resonant circuit.

<3>

The balanced-unbalanced transformer circuit according to <1>, in which the first LC resonant circuit is an LC parallel resonant circuit.

<4>

The balanced-unbalanced transformer circuit according to any one of <1> to <3>, further including a second LC resonant circuit connected between the second end and the reference potential or between the third end and the reference potential, the second LC resonant circuit being disposed where the first LC resonant circuit is not disposed.

<5>

The balanced-unbalanced transformer circuit according to <4>, in which the second LC resonant circuit is an LC parallel resonant circuit.

<6>

An amplifier circuit including:
a first balanced-unbalanced transformer circuit configured to transform an unbalanced signal into a balanced signal;
a differential amplifier configured to amplify the balanced signal output from the first balanced-unbalanced transformer circuit; and
a second balanced-unbalanced transformer circuit configured to transform the balanced signal output from the differential amplifier into an unbalanced signal, in which
one of the first balanced-unbalanced transformer circuit and the second balanced-unbalanced transformer circuit is the balanced-unbalanced transformer circuit according to any one of <1> to <4>, operates as a balanced-unbalanced transformer circuit for a radio frequency signal of one of a first frequency and a second frequency, and does not operate as a balanced-unbalanced transformer circuit for a radio frequency signal of an other of the first frequency and the second frequency, and
an other of the first balanced-unbalanced transformer circuit and the second balanced-unbalanced transformer circuit operates as a balanced-unbalanced transformer circuit for a radio frequency signal of the first frequency and a radio frequency signal of the second frequency.

What is claimed is:

1. A balanced-unbalanced transformer circuit comprising:
a main line constituted by a transmission line having a first end and a second end;
a sub-line coupled to the main line, the sub-line being constituted by a transmission line having a third end and a fourth end;
an unbalanced node to which an unbalanced signal is input and from which the unbalanced signal is output, the unbalanced node being connected to the first end;
a first LC resonant circuit connected between the second end and the reference potential or between the third end and a reference potential;
a first balanced node and a second balanced node to which a balanced signal is input and from which the balanced signal is output,
wherein the main line and the sub-line are coupled to each other such that a direction from the first end toward the second end of the main line is identical to a direction from the third end toward the fourth end of the sub-line,
wherein the second end and the third end are connected to the reference potential, and
wherein the first balanced node and the second balanced node are connected to the unbalanced node and the fourth end, respectively.

2. The balanced-unbalanced transformer circuit according to claim 1, wherein the first LC resonant circuit is an LC series resonant circuit.

3. The balanced-unbalanced transformer circuit according to claim 1, wherein the first LC resonant circuit is an LC parallel resonant circuit.

4. The balanced-unbalanced transformer circuit according to claim 1, further comprising:
a second LC resonant circuit connected between the second end and the reference potential or between the third end and the reference potential,
wherein the second LC resonant circuit is disposed where the first LC resonant circuit is not disposed.

5. The balanced-unbalanced transformer circuit according to claim 2, further comprising:
a second LC resonant circuit connected between the second end and the reference potential or between the third end and the reference potential,
wherein the second LC resonant circuit is disposed where the first LC resonant circuit is not disposed.

6. The balanced-unbalanced transformer circuit according to claim 3, further comprising:
a second LC resonant circuit connected between the second end and the reference potential or between the third end and the reference potential,
wherein the second LC resonant circuit is disposed where the first LC resonant circuit is not disposed.

7. The balanced-unbalanced transformer circuit according to claim 4, wherein the second LC resonant circuit is an LC parallel resonant circuit.

8. An amplifier circuit comprising:
a first balanced-unbalanced transformer circuit configured to transform a first unbalanced signal into a balanced signal, and to output the balanced signal;
a differential amplifier configured to amplify the balanced signal output from the first balanced-unbalanced transformer circuit; and
a second balanced-unbalanced transformer circuit configured to transform the balanced signal output from the differential amplifier into a second unbalanced signal,
wherein one of the first balanced-unbalanced transformer circuit and the second balanced-unbalanced transformer circuit is the balanced-unbalanced transformer circuit according to claim 1, and is configured to operate as a balanced-unbalanced transformer circuit on a radio frequency signal of one of a first frequency and a second frequency, and not on the radio frequency signal of the other of the first frequency and the second frequency, and
wherein the other of the first balanced-unbalanced transformer circuit and the second balanced-unbalanced transformer circuit is configured to operate as a balanced-unbalanced transformer circuit for the radio frequency signal of the first frequency and the radio frequency signal of the second frequency.

9. An amplifier circuit comprising:
a first balanced-unbalanced transformer circuit configured to transform a first unbalanced signal into a balanced signal, and to output the balanced signal;
a differential amplifier configured to amplify the balanced signal output from the first balanced-unbalanced transformer circuit; and
a second balanced-unbalanced transformer circuit configured to transform the balanced signal output from the differential amplifier into a second unbalanced signal,
wherein one of the first balanced-unbalanced transformer circuit and the second balanced-unbalanced transformer circuit is the balanced-unbalanced transformer circuit according to claim 4, and is configured to operate as a balanced-unbalanced transformer circuit on a radio frequency signal of one of a first frequency and a second frequency, and not on the radio frequency signal of the other of the first frequency and the second frequency, and
wherein the other of the first balanced-unbalanced transformer circuit and the second balanced-unbalanced transformer circuit is configured to operate as a balanced-unbalanced transformer circuit on the radio frequency signal of the first frequency and the radio frequency signal of the second frequency.

10. An amplifier circuit comprising:
a first balanced-unbalanced transformer circuit configured to transform a first unbalanced signal into a balanced signal, and to output the balanced signal;
a differential amplifier configured to amplify the balanced signal output from the first balanced-unbalanced transformer circuit; and
a second balanced-unbalanced transformer circuit configured to transform the balanced signal output from the differential amplifier into a second unbalanced signal,
wherein one of the first balanced-unbalanced transformer circuit and the second balanced-unbalanced transformer circuit is the balanced-unbalanced transformer circuit according to claim 7, and is configured to operate as a balanced-unbalanced transformer circuit on a radio frequency signal of one of a first frequency and a second frequency, and not on the radio frequency signal of the other of the first frequency and the second frequency, and
wherein the other of the first balanced-unbalanced transformer circuit and the second balanced-unbalanced transformer circuit is configured to operate as a balanced-unbalanced transformer circuit on the radio frequency signal of the first frequency and the radio frequency signal of the second frequency.
